(19) United States
(12) Patent Application Publication
(10) Pub. No.: US 2013/0345998 A1
(43) Pub. Date: Dec. 26, 2013

(54) ENERGY MANAGEMENT SYSTEM

(71) Applicant: Hitachi, Ltd., Tokyo (JP)

(72) Inventors: Masahiro MATSUBARA, Naka-gun (JP); Kenichi KUWABARA, Abiko (JP); Daisuke HISAJIMA, Tokyo (JP); Junichi YAMADA, Hitachinaka (JP); Yasushi TOMITA, Mito (JP)

(21) Appl. No.: 13/916,064

(22) Filed: Jun. 12, 2013

(30) Foreign Application Priority Data
Jun. 26, 2012 (JP) 2012-142594

(51) Int. Cl. G01R 21/00

(52) U.S. Cl. CPC G01R 21/00
USPC 702/60

(57) ABSTRACT

An energy management system has a configuration including: an air-conditioning schedule energy-saving rate calculating unit which, based on an air-conditioning schedule for the reference time and an air-conditioning schedule that has an energy-saving control content, calculates a relative amount of energy consumed for air-conditioning for each schedule and calculates an effect of energy-saving control; and an amount of consumption converting unit which calculates an amount of energy consumed for air-conditioning that is expected at the reference time, based on an energy-saving rate obtained by the air-conditioning schedule energy-saving rate calculating unit and an amount of energy consumed for air-conditioning when energy-saving control is implemented.

### BACKGROUND OF THE INVENTION

1. Field of the Invention

The present invention relates to a system for controlling air-conditioning equipment of a building and managing the amount of energy consumed.

2. Description of the Related Art

In order to reduce the amount of energy consumed in a building, an energy management system called BEMS (Building Energy Management System) or the like is introduced in a building and the operation of installations such as air-conditioning equipment is controlled. In the case where the energy management system is introduced to carry out energy-saving control, the effect of the energy-saving needs to be shown. That is, it is necessary to compare the amount of energy consumed in the case where energy-saving control is not carried out or in the case where energy-saving control having a smaller effect than the energy-saving control to be applied is carried out, with the amount of energy consumed in the case where the energy-saving control to be applied is carried out, and thus calculate a quantitative effect of the energy-saving control, that is, the amount of reduction in energy consumption and the energy-saving rate.

JP-A-11-328152 is proposed as a method for calculating the amount of energy consumed that is expected in the case where energy-saving control is not carried out or in the case where energy-saving control having a smaller effect than the energy-saving control to be applied is carried out (hereinafter referred to as “reference time”). This publication describes a method in which a period when energy-saving control is not carried out is provided, data of the amount of energy consumed and factors that influence the amount of energy consumed such as weather are collected, and a simulation model for calculating the amount of energy consumed that is expected at a reference time is found.

Also, according to JP-A-2003-070163, a computation formula for calculating the amount of energy consumed when energy-saving control is implemented is found, based on data obtained when energy-saving control is implemented (for example, outdoor temperature, power consumption and the like), and data (outdoor temperature) obtained in the past when energy-saving control is not executed is substituted into this computation formula, thus calculating the amount of consumption expected in the case where energy-saving control is implemented at the same time in the past. By comparing this amount of consumption with the amount of energy consumed that is actually measured at the same time in the past, the effect of the energy-saving control is calculated.

Moreover, according to JP-A-2003-216715, a computation formula for calculating the amount of energy consumed at a non-energy-saving time in the past is found and outdoor temperature and room temperature as environmental conditions at a reference time are substituted into the computation formula, thus calculating the amount of energy consumed that is expected at the reference time. By comparing this amount of energy consumed with the amount of energy consumed when energy-saving control is executed, the effect of the energy-saving control is calculated.

In the method of JP-A-11-328152, a period when energy-saving control is not carried out is provided after the energy management is introduced or updated. However, this leads to an increase in unnecessary energy consumption and therefore the method is not necessarily acceptable.

In the method of JP-A-2003-070163, data obtained in the past when energy-saving control is not carried out is required. However, such data cannot necessarily be obtained. Also, the amount of reduction in energy consumption and the energy-saving rate calculated by this method are values obtained on the assumption that there is a case where energy-saving control is not carried out in the past, and therefore are not values that can be calculated in the case where energy-saving control is carried out at present. If the energy consumption trend (for example, the size of the amount of heat load) is the same before and after the introduction of the energy-saving control, the energy-saving rate obtained in this method can be considered the same at the present time. However, there are cases where different energy-saving control or utilization of the installation that causes energy-saving is carried out in the past. In such cases, the effect of the present energy-saving control cannot be calculated.

In the method of JP-A-2003-216715, the computation formula for the amount of consumption contains room temperature, which is a value influenced by a control parameter (preset temperature). Since a part of the heat load associated with the amount of energy consumed by the air-conditioning equipment is generated by the difference between outside temperature and room temperature, this method is considered effective in the case where the amount of energy consumed can be measured per small section, such as per room. This is because if the measuring section is smaller than a certain scale, the correlation between room temperature and the amount of heat load is considered stronger. However, since room temperature varies depending on place, there is a risk that the correlation with the amount of energy consumed may fall. Also, in the actual energy management system, the costs of installations and construction increase if many measuring points are provided. Therefore, in many cases, the amount of electric power is only measured in each of roughly divided sections, for example, one point in a building or each tenant. Moreover, parameters for calculating the amount of energy consumed (for example, room temperature) need to be adjusted in accordance with the measuring section for the amount of energy consumed, such as taking the average among places. Also, this method requires data obtained during a period when energy-saving control is not carried out, and therefore has a problem that this leads to an increase in unnecessary energy consumption.

Meanwhile, as a method for calculating the effect of energy-saving control, in addition to values related to the environment such as outdoor temperature, a value that is operated in energy-saving control (for example, the preset temperature or on-off control of the air-conditioning machine) may be entered as a parameter into a model for the amount of consumption (for example, a computation formula or computation procedure). To construct this model, data can be used irrespective of whether there is energy-saving control or not when the data is measured. The model can also be found based on regression calculation or the like. If such a consumption amount model is constructed, the past energy-saving effect can be calculated, and the amount of energy consumed in the future and the amount of reduction in consumption and the energy-saving rate due to energy-saving control can be estimated, assuming future control contents.

However, generally, even when control parameters such as preset temperature are incorporated in a model for calculating the amount of energy consumed, the model may not be effective in some cases unless the parameters are statistically significant. As the causes, the insufficiency of measuring points as in the foregoing example and the larger influence of an unmeasured parameter on the amount of consumption than of a measured control parameter may be considered.

### SUMMARY OF THE INVENTION

In order to solve the foregoing problems, the invention has, for example, the configuration described in the appended claims.

According to the invention, even if there is no data obtained at a reference time or a period of the reference time is not provided, the amount of consumption expected at the reference time can be calculated and the energy-saving effect can be quantitatively found.

Other problems, configurations and advantages than those described above will be clarified in the following description of embodiments.

### BRIEF DESCRIPTION OF THE DRAWINGS

FIG. 1 shows a system configuration of the invention.

FIG. 2 shows the functional configuration of an energy management server.

FIG. 3 shows a data flow for conversion of the amount of consumption.

FIG. 4 is a flowchart of processing to calculate the amount of consumption expected at a reference time.

FIGS. 5A and 5B show air-conditioning schedules for the reference time and for the time when energy-saving control is implemented.

FIGS. 6A and 6B are tables for calculating the relative amount of consumption.

FIG. 7 is a graph showing the accumulated amount of consumption displayed on an amount of energy consumed display unit.

FIG. 8 is a flowchart of processing to calculate a predicted value of the amount of consumption expected at the reference time.

FIG. 9 is a flowchart of processing to calculate a predicted value of the amount of consumption expected at the reference time.

FIG. 10 is a flowchart of processing to predict the amount of consumption including a correction.

FIG. 11 is a graph of the amount of consumption showing the amount of energy consumed for air-conditioning per day.

### DESCRIPTION OF PREFERRED EMBODIMENTS

Hereinafter, an embodiment of the invention will be described with reference to the drawings.

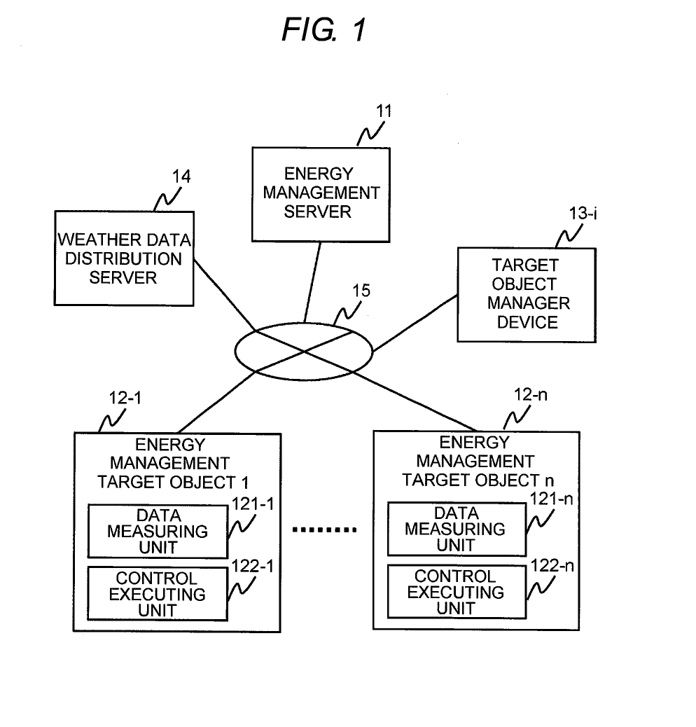

FIG. 1 shows the configuration of an energy management system to which the invention is applied.

An energy management server 11 carries out energy management in some sections or all the sections in a building. Specifically, the energy management server 11 accumulates data related to energy consumption and generates graph display data. The energy management server 11 also generates data to command control contents of installations.

An energy management target object 12-x (x=1 to n) is a target of energy management carried out by the energy management server 11. The energy management target object 12-x is provided with a data measuring unit 121-x which collects measuring data such as the amount of energy consumed and operation data such as the on-off state of an air-conditioning machine from installations within the energy management target object 12-x and transmits the collected data to the energy management server 11 via a network 15. The energy management target object 12-x is also provided with a control executing unit 122-x which receives control command data transmitted from the energy management server 11 via the network 15 and executes control of installations in the energy management target object 12-x. The data measuring unit 121-x and the control executing unit 122-x are controllers and are connected to one or plural controllers which exist similarly in the energy management target object 12-x, control installed equipment and measure data, via a network not shown.

A target object manager device 13-i (i=1 to m) has a screen display device and an input device such as keyboard and mouse. The target object manager device 13-i acquires data about the energy management target object 12-x from the energy management server 11 via the network 15 and displays the acquired data to the manager in the energy management target object 12-x. The target object manager device 13-i accepts an input by the manager with respect to the setting of control of installations of the energy management target object 12-x and transmits the input to the energy management server 11 via the network 15.

A weather data distribution server 14 accumulates measured data and prediction data about the weather such as outdoor temperature in each place and distributes the data via the network 15.

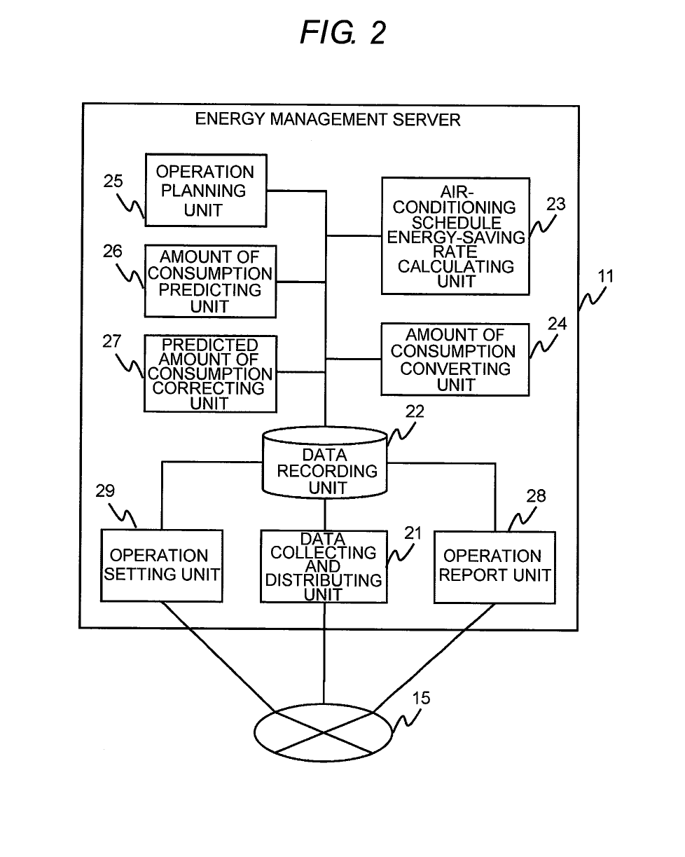

FIG. 2 shows the functional configuration in the energy management server 11.

A data collecting and distributing unit 21 receives measured data from the data measuring unit 121-x of the energy management target object 12-x via the network 15 and stores the measured data in a data recording unit 22. The data collecting and distributing unit 21 also transmits control command data stored in the data recording unit 22 to the control executing unit 122-x of the energy management target object 12-x. The measured data and the control command data are given an identification number of the energy management target object 12-x. Therefore, on the data recording unit 22, these data can be searched for by using the identification number together as well as data type and time and date, and data transmitter and receiver of these data can be specified.

The measured data transmitted by the data measuring unit 121-x to the data collecting and distributing unit 21 includes at least the amount of energy consumed for air-conditioning. The unit of the amount of energy consumed for air-conditioning is, for example, [kWh/day]. In this example, the amount of consumption is measured per day. However, the time interval is not limited to this example.

As for the timing when the data measuring unit 121-x transmits data to the data collecting and distributing unit 21, for example, data for one day is transmitted at predetermined time of the following day. As for the timing when the data collecting and distributing unit 21 transmits data to the control executing unit 122-x, for example, control schedule data for one day is transmitted at predetermined time of the previous day. Also, an event-like control command is transmitted at the time point when the control command is stored in the data recording unit 22.

Moreover, the data collecting and distributing unit 21 receives weather data of each place from the weather data distribution server 14 and stores the weather data in the data recording unit 22. The weather data includes at least outside temperature. The weather data is given an identification number of the place and therefore can be searched for on the data recording unit 22 by using the identification number as well data type and time and date.

An air-conditioning schedule energy-saving rate calculating unit 23 calculates an air-conditioning energy consumption reduction rate (hereinafter simply referred to as “energy-saving rate”) for the time when energy-saving control is implemented in relation to a reference time, using air-conditioning schedule data as an energy-saving control content that is stored in the data recording unit 22 and transmitted to the control executing unit 122-x and air-conditioning schedule data as an air-conditioning machine operation method for the reference time that is stored in the data recording unit 22 with respect to the energy management target object 12-x, as inputs. Since the air-conditioning schedule for the time when energy-saving control is implemented can be changed daily, the energy-saving rate is calculated every unit time of the amount of consumption (every day) and stored in the data recording unit 22.

An amount of consumption converting unit 24 uses the amount of energy consumed for air-conditioning when energy-saving control is implemented, as an input, and converts this amount of energy consumed for air-conditioning into the amount of energy consumed for air-conditioning that is expected at the reference time, using the energy-saving rate calculated by the air-conditioning schedule energy-saving rate calculating unit 23. Alternatively, the amount of consumption converting unit 24 uses the amount of energy consumed for air-conditioning at the reference time, as an input, and converts this amount of energy consumed for air-conditioning into the amount of energy consumed for air-conditioning that is expected when energy-saving control is implemented, using the energy-saving rate calculated by the air-conditioning schedule energy-saving rate calculating unit 23. The amount of energy consumed for air-conditioning before the conversion is stored in the data recording unit 22. The amount of energy consumed for air-conditioning after the conversion is also stored in the data recording unit 22.

An operation planning unit 25 generates air-conditioning schedule data for the time when energy-saving control is implemented, for each energy management target object 12-x, and stores the generated data in the data recording unit 22. The energy-saving control method, that is, the method for generating air-conditioning schedules is not included in the invention and therefore is not described here.

An amount of consumption predicting unit 26 calculates the amount of energy consumed for air-conditioning that is predicted for the future, based on the past amount of energy consumed for air-conditioning stored in the data recording unit 22, and stores the calculated amount of energy consumed for air-conditioning in the data recording unit 22. As a prediction method, for example, a regression formula is found, using the amount of energy consumed for air-conditioning per day as a response variable and using the daily average of outdoor temperature as an explanatory variable. A prediction model is constructed for each energy management target object 12-x.

A predicted amount of consumption correcting unit 27 calculates an error rate of the predicted amount of energy consumed for air-conditioning, based on the predicted amount of energy consumed for air-conditioning when energy-saving control is implemented on a certain day, which is calculated in the past by the amount of consumption predicting unit 26 and stored in the data recording unit 22, and the amount of energy consumed for air-conditioning when energy-saving control is implemented on the same day, which is measured later and stored in the data recording unit 22. Based on the error rate, the predicted amount of consumption correcting unit 27 finds a correction rate for the predicted amount of consumption calculated by the amount of consumption predicting unit 26 and the energy-saving rate calculated by the air-conditioning schedule energy-saving rate calculating unit 23, and stores the correction rate in the data recording unit 22. This correction rate is for improving the accuracy of the predicted amount of consumption.

An operation report unit 28 transmits the air-conditioning schedule data for the time when energy-saving control is implemented, which is stored in the data recording unit 22, and the actually measured value of the past amount of energy consumed for air-conditioning and the predicted value of the future amount of energy consumed for air-conditioning, with respect to the energy management target object 12-x, in the form of display data in the HTML (Hyper Text Markup Language) format or the like to the target object manager device 13-i via the network 15. The operation report unit 28 accepts the identification number of the energy management target object 12-x inputted to the target object manager device 13-i and the designation of display target time and date or the like, and generates display data.

An operation setting unit 29 receives, via the network 15, the setting about energy-saving control inputted to the target object manager device 13-i, gives the identification number of the energy management target object 12-x, and stores the setting in the data recording unit 22. The setting content of energy-saving control includes at least the air-conditioning schedule for the reference time.

The functions within the energy management server 11 are realized as a program. The program is stored in a storage device such as a ROM (Read Only Memory) or hard disk in the energy management server 11. The program is executed by an arithmetic operation unit of the energy management server 11, using a temporary storage device such as RAM (Random Access Memory) of the energy management server 11. The result of the arithmetic operation is stored in the storage device such as the hard disk. Various data accumulated in the data recording unit 22 are also stored in the storage device such as the hard disk of the energy management server 11. Also, the operation report unit 28 and the operation setting unit 29 transmit and receive data on the network 15, using a communication device of the energy management server 11.

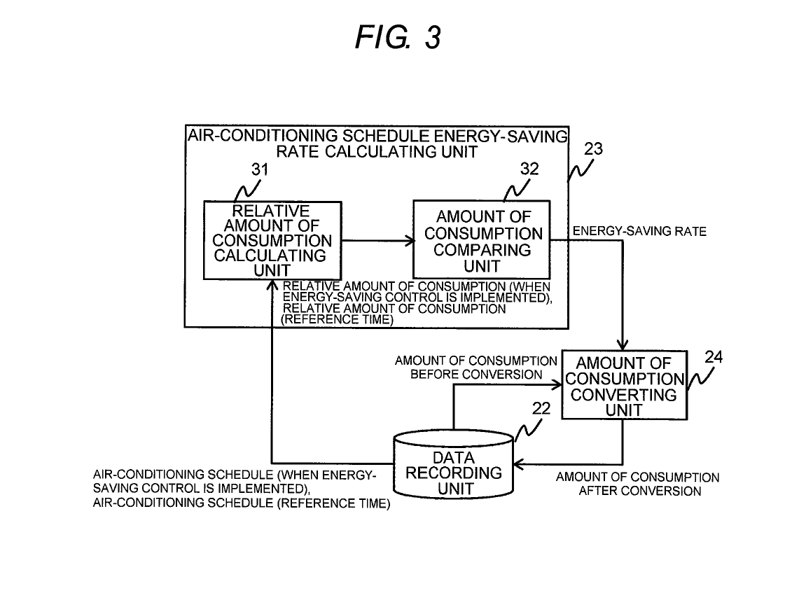

FIG. 3 shows the functional configuration of the air-conditioning schedule energy-saving rate calculating unit 23. A relative amount of consumption calculating unit 31 calculates a relative amount of energy consumed for air-conditioning corresponding to air-conditioning schedule data that is inputted. An amount of consumption comparing unit 32 calculates the energy-saving rate for the time when the energy-saving control is implemented in relation to the reference time, based on the relative amount of energy consumed for air-conditioning in relation to the air-conditioning schedule data for the reference time and the relative amount of energy consumed for air-conditioning in relation to the air-conditioning schedule data for the time when energy-saving control is implemented, calculated by the relative amount of consumption calculating unit 31. After that, the amount of consumption converting unit 24 uses, as inputs, the calculated energy-saving rate and the amount of energy consumed for air-conditioning when energy-saving control is implemented, which is the amount of energy consumed for air-conditioning before conversion stored in the data recording unit 22, and converts the amount of energy consumed for air-conditioning into the amount of energy consumed for air-conditioning expected at the reference time. The converted amount of energy consumed for air-conditioning is stored in the data recording unit 22.

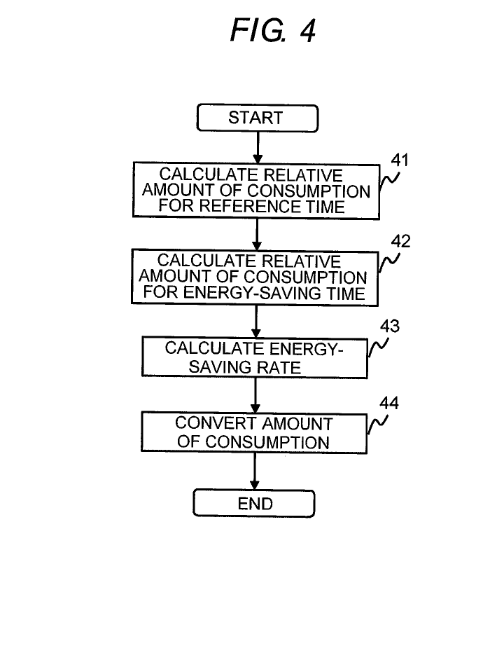

FIG. 4 shows a processing flow for the air-conditioning schedule energy-saving rate calculating unit 23 and the amount of consumption converting unit 24 to calculate the amount of energy consumed for air-conditioning expected at the reference time.

Step 41, the relative amount of consumption calculating unit 31 acquires the air-conditioning schedule data for the reference time from the data recording unit 22 and calculates the relative amount of energy consumed for air-conditioning at the reference time.

In Step 42, the relative amount of consumption calculating unit 31 acquires the air-conditioning schedule data for the time when energy-saving control is implemented from the data recording unit 22 and calculates the relative amount of energy consumed for air-conditioning when energy-saving control is implemented.

In Step 43, the amount of consumption comparing unit 32 calculates the energy-saving rate for the time when energy-saving control is implemented in relation to the reference time, based on the relative amount of energy consumed for air-conditioning at the reference time, calculated in Step 41, and the relative amount of energy consumed for air-conditioning when energy-saving control is implemented, calculated in Step 42.

In Step 44, the amount of consumption converting unit 24 acquires the data of the amount of energy consumed for air-conditioning before conversion from the data recording unit 22, converts the amount of energy consumed for air-conditioning based on the energy-saving rate calculated in Step 43, and stores the converted amount of energy consumed for air-conditioning in the data recording unit 22. As a conversion method, when the energy-saving rate is a percentage, if the amount of energy consumed for air-conditioning before conversion is the value for the reference time, then this value is multiplied by (100−energy-saving rate)/100, whereas if the amount of energy consumed for air-conditioning before conversion is the value for the time when energy-saving control is implemented, then the value is multiplied by 100/(100−energy-saving rate). However, in the latter case, the conversion cannot be carried out when the energy-saving rate is 100%, that is, when the air-conditioning machine is totally stopped. The amount of energy consumed for air-conditioning that is observed when the energy-saving rate is 100% is treated, for example, as a base load, and at the reference time, the same amount of consumption as when energy-saving control is implemented is used.

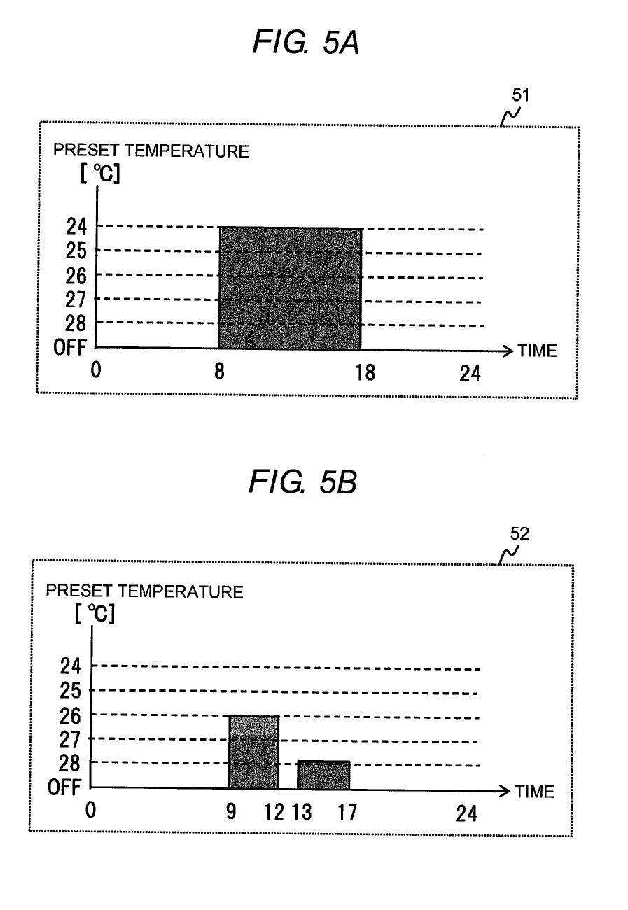

FIGS. 5A and 5B show an example of air-conditioning schedule data. FIG. 5A shows air-conditioning schedule data for the reference time. FIG. 5B shows air-conditioning schedule data for the time when energy-saving control is implemented.

According to an air-conditioning schedule 51, which is the air-conditioning schedule data for the reference time, shown in FIG. 5A, the air-conditioning machine is set to operate at a preset temperature of 24° C. from 8:00 to 18:00 and stop during other time slots. Meanwhile, according to an air-conditioning schedule 52, which is the air-conditioning schedule data for the time when energy-saving control is implemented, shown in FIG. 5B, the air-conditioning machine is set to operate at a preset temperature of 26° C. from 9:00 to 12:00, then operate at a preset temperature of 28° C. from 13:00 to 17:00, and stop during the remaining time slots. This schedule 52 is generated by the operation planning unit 25.

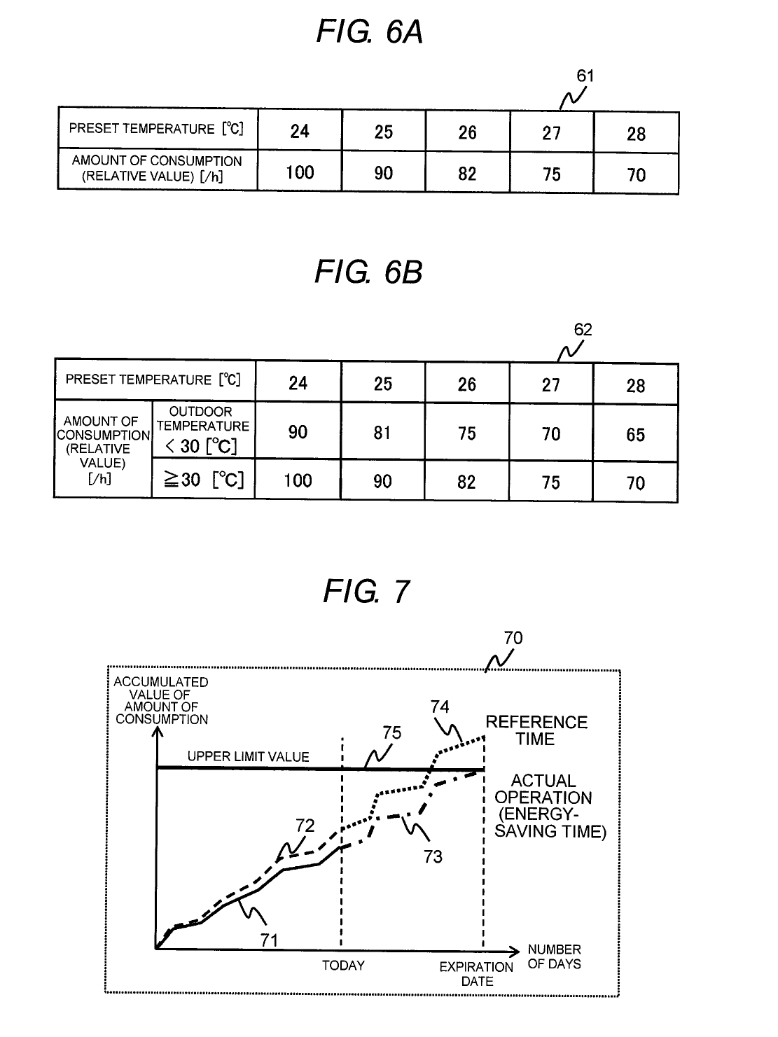

FIGS. 6A and 6B show an example of a relative amount of consumption calculation table held in the relative amount of consumption calculating unit 31. FIG. 6A is a relative amount of consumption calculation table 61 used to calculate the relative amount of energy consumed for air-conditioning, based on preset temperature. FIG. 6B is a relative amount of consumption calculation table 62 used to calculate the relative amount of energy consumed for air-conditioning, based on outdoor temperature in addition to preset temperature.

The relative amount of consumption calculating unit 31 calculates the relative amount of energy consumed for air-conditioning in the air-conditioning schedule, for example, using the relative amount of consumption calculation tables 61, 62 as shown in FIGS. 6A and 6B. Specifically, when the relative amount of consumption calculation table 61 is used, the relative amount of energy consumed for air-conditioning is calculated for each time point in the air-conditioning schedule data, based on the preset temperature for the time when the air-conditioning machine is on. Then, the relative amount of energy consumed for air-conditioning at each time point is calculated with respect to all the time points in the air-conditioning schedule data, and these values are summed up. Thus, the relative amount of energy consumed for air-conditioning in the air-conditioning schedule can be calculated.

The relative amount of consumption calculation table 61 shows data in the case where only preset temperature is used for the calculation of the relative amount of energy consumed for air-conditioning. When this relative amount of consumption calculation table 61 is used, the relative amount of consumption in relation to the air-conditioning schedule 51 for the reference time shown in FIG. 5A can be calculated as 1000, and the relative amount of consumption in relation to the air-conditioning schedule 52 for the time when energy-saving control is implemented shown in FIG. 5B can be calculated as 526. Based on these values, the energy-saving rate of the air-conditioning schedule 52 for the time when energy-saving control is implemented in relation to the air-conditioning schedule 51 for the reference time can be calculated as 47.4%.

The relative amount of consumption calculation table 62 shows data in the case where outdoor temperature as well as preset temperature is used for the calculation of the relative amount of energy consumed for air-conditioning. When this relative amount of consumption calculation table 62 is used, if the outdoor temperature is 28° C. on daily average, the relative amount of consumption in relation to the air-conditioning schedule 51 for the reference time is 900, and the relative amount of consumption in relation to the air-conditioning schedule 52 for the time when energy-saving control is implemented is 485. The energy-saving rate is approximately 46.1%.

The method for calculating the relative amount of consumption by the relative amount of consumption calculating unit 31 is not limited to the above method, and other methods may also be used. For example, a simulation for the amount of energy consumed for air-conditioning based on heat load calculation using fixed values for the floor area and building materials of the building or the like may be used.

With the above processing, even if there is no data that is measured under the same condition as the reference time, the amount of energy consumed for air-conditioning expected at the reference time is calculated and compared with the measured value of the amount of energy consumed for air-conditioning when energy-saving control is implemented. Thus, the effect of the energy-saving control can be found quantitatively.

FIG. 7 is an example of a graph generated by the operation report unit 28.

In a graph 70, the horizontal axis represents the number of days and the vertical axis represents the accumulated value of the amount of energy consumed for air-conditioning per day, with respect to the energy management target object 12-x. The display target period on the horizontal axis of the graph 70 is a target period of the energy-saving control by the operation planning unit 25. This period is stored in the data recording unit 22.

In this example, an air-conditioning schedule 52 for today and after is created in such a way that the energy-saving control content employed by the operation planning unit 25 fits within an upper limit value 75 of the amount of energy consumed for air-conditioning during the current control period. Here, the upper limit value 75 of the amount of energy consumed for air-conditioning during a predetermined period is a preset value that is inputted to the target object manager device 13-i, received by the operation setting unit 29 and stored in the data recording unit 22.

An accumulated amount of consumption graph line 71 shows the accumulated value of the amount of energy consumed for air-conditioning for the time when energy-saving control is implemented, measured from the start day of the current control target period until yesterday and stored in the data recording unit 22.

An accumulated amount of consumption graph line 72 shows the accumulated value of the amount of energy consumed for air-conditioning expected at the reference time during the same period. The daily value of the accumulated amount of consumption graph line 72 is the amount of consumption obtained by calculating the daily amount of consumption on the accumulated amount of consumption graph line 71 by the air-conditioning schedule energy-saving rate calculating unit 23 and then converting the amount of consumption by the amount of consumption converting unit 24 using the energy-saving rate recorded daily in the data recording unit 22.

An accumulated amount of consumption graph line 73 shows the accumulated value of the predicted amount of energy consumed for air-conditioning when energy-saving control is implemented, predicted from the day in question until the end day of the current control target period and stored in the data recording unit 22.

An accumulated amount of consumption graph line 74 shows the accumulated value of the predicted amount of energy consumed for air-conditioning expected at the reference time during the same period.

In the graph 70, it can be seen that the accumulated amount of consumption fits within the designated upper limit at the end point of the current control period, if energy-saving control is implemented. Meanwhile, the accumulated amount of consumption expected at the reference time exceeds the designated upper limit. Thus, the effect of the energy-saving control is clear. That is, in the case where an amount of energy consumed display unit which displays the amount of energy consumed for air-conditioning is provided, an upper limit value for the purpose of restraining the amount of energy consumed for air-conditioning during a predetermined period within a designated predetermined value, the accumulated value of the amount of energy consumed for air-conditioning when energy-saving control is implemented during the predetermined period, and the accumulated value of the amount of energy consumed for air-conditioning at the reference time during the period can be displayed. Thus, when the accumulated value of the amount of energy consumed for air-conditioning when energy-saving control is implemented is within the upper limit value whereas the accumulated value of the amount of energy consumed for air-conditioning at the reference time is not within the upper limit value, the effect of the energy-saving control can be displayed visually and clearly.

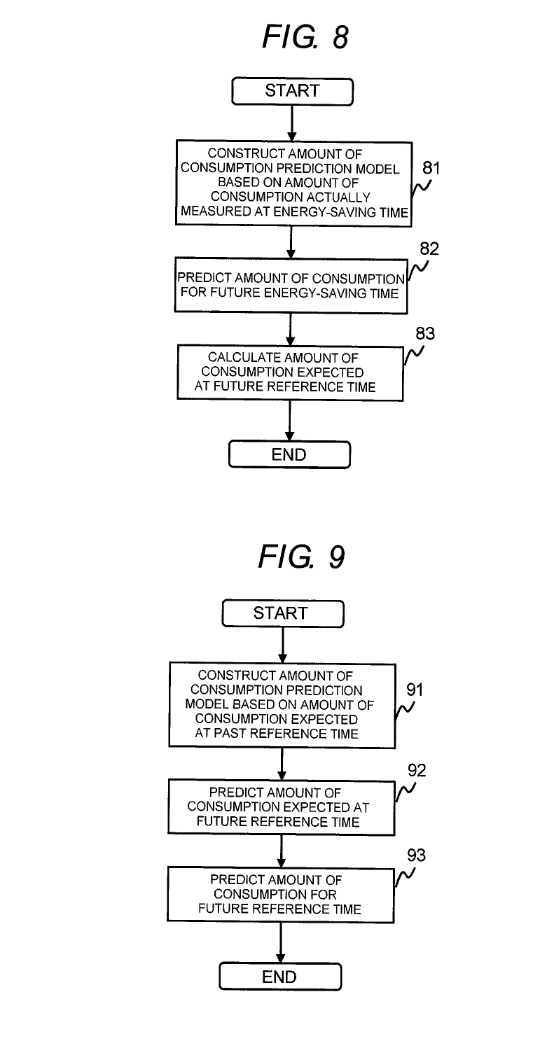

FIG. 8 shows a processing flow to predict the future amount of consumption that is used to generate the accumulated amount of consumption graph lines 73 and 74.

In Step 81, the amount of consumption predicting unit 26 constructs an amount of consumption prediction model, using the amount of consumption measured when energy-saving control is implemented, that is, the daily value on the accumulated amount of consumption graph line 71, as well as the weather data (outdoor temperature or the like) for the same day stored in the data recording unit 22. As an example of the amount of consumption prediction model, a regression formula using outdoor temperature as an explanatory variable may be used.

In Step 82, the amount of consumption predicting unit 26 inputs the weather data stored in the data recording unit 22 into the amount of consumption prediction model obtained in Step 81, calculates the daily amount of consumption until the end day of the current control target period, and stores the calculated amount of consumption in the data recording unit 22. This amount of consumption is the value for the time when energy-saving control is implemented and the daily value on the accumulated amount of consumption graph line 73.

In Step 83, the predicted amount of energy consumed for air-conditioning when energy-saving control is implemented, obtained in Step 82, is converted to the predicted amount of energy consumed for air-conditioning at the reference time in the processing flow of FIG. 4 and the result is stored in the data recording unit 22. Then, the processing flow ends. The predicted amount of energy consumed for air-conditioning at the reference time, calculated here, is the daily value on the accumulated amount of consumption graph line 74. In this case, in Step 42 of FIG. 4, the energy-saving rate is calculated using the air-conditioning schedule data generated by the operation planning unit 25, which is a plan to be applied to the future including the day in question.

With the above processing, by separating the prediction unit for the amount of energy consumed and the unit for reflecting the effect of energy-saving control on the calculated amount of consumption, and calculating the effect of energy-saving control using the above method, the predicted amount of energy consumed for air-conditioning expected at the reference time in the future and the predicted amount of energy consumed for air-conditioning when energy-saving control is implemented are calculated even if there is no data that is measured under the same condition as the reference time. Thus, the effect of the energy-saving control can be found quantitatively.

FIG. 9 shows a processing flow to predict the future amount of consumption, as in FIG. 8. However, the processing content is different from FIG. 8.

In Step 91, the amount of consumption predicting unit 26 constructs an amount of consumption prediction model, using the amount of energy consumed for air-conditioning expected at the past reference time, that is, the daily value on the accumulated amount of consumption graph line 72, as well as the weather data (outdoor temperature or the like) for the same day stored in the data recording unit 22.

In Step 92, the amount of consumption predicting unit 26 inputs the weather data stored in the data recording unit 22 into the amount of consumption prediction model obtained in Step 91, calculates the daily amount of consumption until the end day of the current control target period, and stores the calculated amount of consumption in the data recording unit 22. This amount of consumption is a value for the reference time and the daily value on the accumulated amount of consumption graph line 74.

In Step 93, the predicted amount of energy consumed for air-conditioning at the reference time obtained in Step 92 is converted into the predicted amount of energy consumed for air-conditioning when energy-saving control is implemented, in the processing flow of FIG. 4, and the result is stored in the data recording unit 22. Then the processing flow ends. This amount of consumption is the daily value on the accumulated amount of consumption graph line 73. In this case, the calculation of the energy-saving rate using the future air-conditioning schedule data generated by the operation planning unit 25 in Step 42 is similar to Step 83.

In the processing flow of FIG. 9, the amount of consumption used for the construction of the amount of consumption prediction model is a value for the reference time and the predicted amount of consumption is a value for the reference time, too. Therefore, even if the daily air-conditioning schedule is changed, causing the energy-saving rate to vary, this variance has little influence.

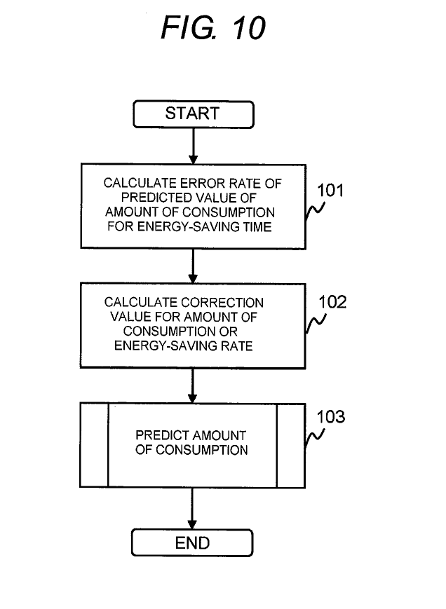

FIG. 10 shows a flow of processing to predict the amount of energy consumed for air-conditioning, including correction of the predicted amount of consumption or the energy-saving rate.

In Step 101, the predicted amount of consumption correcting unit 27 calculates the error rate of the predicted amount of energy consumed for air-conditioning, based on the predicted amount of energy consumed for air-conditioning when energy-saving control is implemented on a certain day and the amount of energy consumed for air-conditioning when energy-saving control is implemented on the same day that is measured later, and stores the error rate in the data recording unit 22 daily. For example, if the predicted amount of consumption is 100 and the measured amount of consumption is 90, the error rate is −0.1. As the error rate, a moving average may be taken.

In Step 102, the predicted amount of consumption correcting unit 27 calculates a correction rate for the predicted amount of energy consumed for air-conditioning for the future or for the energy-saving rate found from the air-conditioning schedule data for the time when energy-saving control is implemented, using the error rate obtained in Step 101. When correcting the predicted amount of consumption, the correction rate is, for example, 1+error rate. When correcting the energy-saving rate, the correction rate is, for example, 1/(1+error rate).

In Step 103, the energy-saving rate and the predicted amount of energy consumed for air-conditioning are found in the processing flow of FIG. 8 or FIG. 9. After that, the processing flow ends. However, if it is assumed in Step 102 that the predicted amount of consumption is to be corrected, the calculated predicted amount of consumption is multiplied by the correction rate. If it is assumed in Step 102 that the energy-saving rate is to be corrected, the energy-saving rate is multiplied by the correction rate and then the predicted amount of consumption is found.

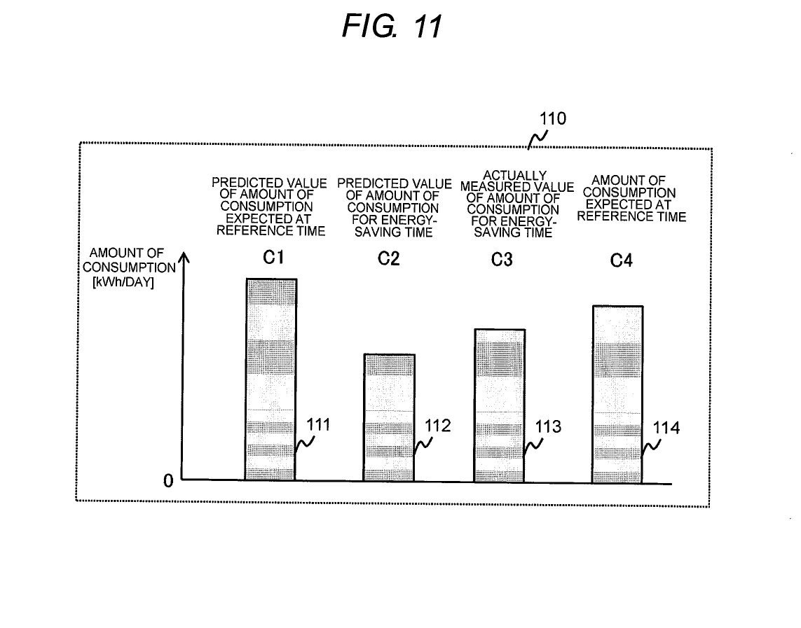

FIG. 11 shows an example of correction based on the processing flow of FIG. 10. An amount of consumption graph 110 shows the amount of energy consumed for air-conditioning per day for a certain day. A graph bar 111 shows an amount of consumption C1 expected at the reference time that is predicted in the past. A graph bar 112 shows an amount of consumption C2 for the time when energy-saving control is implemented that is predicted in the past. A graph bar 113 shows an amount of consumption C3 for the time when energy-saving control is implemented that is measured later. A graph bar 114 shows an amount of consumption C4 expected at the reference time that is obtained as the amount of consumption converting unit 24 converts the value of the graph bar 113. Here, the error rate calculated in Step 101 is (C3−C2)/C2. If it is assumed in Step 102 that the energy-saving rate is to be corrected, the correction rate is C2/C3. The original energy-saving rate is 1−C2/C1. Therefore, the energy-saving rate after correction is (C1−C2)/C3. That is, C4×{1−(C1−C2)/C3}=C3 results.

As described above, even when the accuracy of the relative amount of consumption calculation model is low in its initial setting, the calculation accuracy of the predicted amount of consumption is improved by the correction of the predicted amount of consumption or the energy-saving rate. Therefore, practicality of the calculation method for the energy-saving effect according to the invention can be enhanced.

1. An energy management system comprising:
an air-conditioning schedule energy-saving rate calculating unit which, based on an air-conditioning schedule for a reference time, an air-conditioning schedule for the time when energy-saving control is implemented and an amount of energy consumed for air-conditioning in relation to a preset temperature of air-conditioning, calculates an amount of energy consumed for air-conditioning with respect to each of the air-conditioning schedule for the reference time and the time when the energy-saving control is implemented, and
which, based on the amount of energy consumed for air-conditioning with respect to each, calculates a value indicating an effect of the energy-saving control of the amount of energy consumed for air-conditioning in the air-conditioning schedule for the time when the energy-saving control is implemented in relation to the air-conditioning schedule for the reference time; and
an amount of consumption converting unit which calculates at least one of an amount of energy consumed for air-conditioning in the case where the air-conditioning schedule for the reference time is implemented based on the value indicating the effect of the energy-saving control and the amount of energy consumed for air-conditioning when the energy-saving control is implemented, and an amount of energy consumed for air-conditioning that is expected when the energy-saving control is implemented based on the value indicating the effect of the energy-saving control and the amount of energy consumed for air-conditioning at the reference time.

2. The energy management system according to claim 1, wherein the effect of the energy-saving control is an energy-saving rate of the amount of energy consumed for air-conditioning in the air-conditioning schedule for the time when the energy-saving control is implemented, in relation to the air-conditioning schedule for the reference time.

3. The energy management system according to claim 1, comprising an amount of consumption predicting unit which calculates an amount of energy consumed for air-conditioning that is predicted for the future, based on a past amount of energy consumed for air-conditioning and data of a value related to external environment,
wherein the past amount of energy consumed for air-conditioning is a value that is actually measured when the energy-saving control is implemented, and
the amount of consumption converting unit converts a predicted amount of energy consumed for air-conditioning when the energy-saving control is implemented that is calculated by the amount of consumption predicting unit into a predicted amount of energy consumed for air-conditioning at the reference time.

4. The energy management system according to claim 1, comprising an amount of consumption predicting unit which calculates an amount of energy consumed for air-conditioning that is predicted for the future, based on a past amount of energy consumed for air-conditioning and data of a value related to external environment,
wherein the past amount of energy consumed for air-conditioning is an amount of energy consumed for air-conditioning at the reference time that is obtained by inputting a value that is actually measured when the energy-saving control is implemented, into the amount of consumption converting unit, and
the amount of consumption converting unit converts a predicted amount of energy consumed for air-conditioning at the reference time that is calculated by the amount of consumption predicting unit into a predicted amount of energy consumed for air-conditioning when the energy-saving control is implemented.

5. The energy management system according to claim 3, comprising a predicted amount of consumption correcting unit which corrects the value indicating the effect of the energy-saving control and/or the predicted amount of energy consumed for air-conditioning,
wherein the predicted amount of consumption correcting unit corrects the value indicating the effect of the energy-saving control and/or the predicted amount of energy consumed for air-conditioning, based on a comparison between the predicted amount of energy consumed for air-conditioning when the energy-saving control is implemented that is calculated by the amount of consumption converting unit and the amount of energy consumed for air-conditioning that is actually measured when the energy-saving control is implemented.

6. The energy management system according to claim 1, comprising an amount of energy consumed display unit which displays the amount of energy consumed for air-conditioning,
wherein an accumulated value of the amount of energy consumed for air-conditioning when the energy-saving control is implemented during a predetermined period, and an accumulated value of the amount of energy consumed for air-conditioning at the reference time during the predetermined period are displayed.

7. The energy management system according to claim 6, wherein the amount of energy consumed display unit displays an upper limit value that is designated to restrain the amount of energy consumed for air-conditioning within a predetermined value in the energy-saving control.
